(19) United States
(12) Patent Application Publication
(10) Pub. No.: US 2021/0242694 A1
(43) Pub. Date: Aug. 5, 2021

(54) BATTERY CONTROLLER

(71) Applicant: Without-Jamaar Holding B.V., Halfweg (NL)

(72) Inventor: Bas DE LANG, Halfweg (NL)

(21) Appl. No.: 17/235,470

(22) Filed: Apr. 20, 2021

Related U.S. Application Data
(63) Continuation of application No. PCT/SG2019/050257, filed on May 7, 2019.

(30) Foreign Application Priority Data
May 8, 2018 (SG) 10201803866S

(51) Int. Cl. H02J 7/00; H01M 10/44; G01R 31/3842; H01M 10/42

(52) U.S. Cl. CPC H02J 7/00036; H01M 10/44; H01M 2010/4271; H01M 10/425; H01M 2010/4278; G01R 31/3842

(57) ABSTRACT

The application provides a battery. The battery includes a battery module for providing an electric current and a controller module. The controller module includes a switch for controlling an electric current flowing from the battery module and a voltage control unit for receiving the electric current from the battery module, for providing measurements of the electric current, and for providing measurements of a voltage of the battery module. The controller module further includes a communication unit for receiving commands from an external computing device via a wireless means. The controller module also includes a computing processor unit for generating control signals according to the commands from the communication unit and for sending the generated control signals to the switch and/or the voltage control unit. The battery also includes a cylindrical battery housing enclosing the battery module and the controller module.

### CROSS-REFERENCE TO RELATED APPLICATIONS

This application is a continuation under 35 U.S.C. §120 of International Application No. PCT/SG2019/050257, filed May 7, 2019, which takes priority from Singapore Patent Application No. 10201803866S, filed May 8, 2018, the contents of each of which are hereby incorporated by reference in their entirety.

### FIELD OF THE INVENTION

The application relates to a battery. In particular, the application relates to a battery with a control module.

### BACKGROUND

Batteries of AA-size or AAA-size are commonly used in many electronic devices. For example, such batteries are often used to power LED lights, ambiance lights, decoration lights, and other lighting devices. Such battery-powered lighting device are often used for decorative purpose and they are handy and portable as they do not require electrical cables and power plugs to operate.

U.S. Pat. No. 8,350,529 B2 discloses a method and an apparatus for a Battery Management System (BMS) for controlling of charging and discharging of a plurality of battery cells. Each battery cell has a plurality of control circuits, which monitor and control the charging of the battery cell. These battery cells are controlled by a microcontroller, which shunts current around the battery cell if it is fully charged and stops discharging if a battery cell is fully discharged in order to prevent damage to the other battery cells.

U.S. Pat. No. 5,606,242 A describes a smart battery, which reports predefined battery parameters to an external device having a power management system. The smart battery includes at least one rechargeable cell connected to a pair of terminals to provide electrical power to an external device during a discharge mode and to receive electrical power during a charge mode. The discharge mode and the charge mode are determined by a remote device. The smart battery also includes a data bus for reporting predefined battery identification and charge parameters to the external device. The smart battery further includes multiple analog devices for generating analog signals representative of battery voltage and current at said terminals, and an analog signal representative of battery temperature at the rechargeable cell. The smart battery also includes a hybrid integrated circuit (IC) having a microprocessor for receiving the analog signals and converting them to digital signals representative of battery voltage, current and temperature, and calculating actual charge parameters over time from the digital signals.

### SUMMARY OF INVENTION

An object of this application is to provide an improved battery and a system for controlling operational states of the improved battery.

The application provides an improved battery for an electronic device. The electronic device often refers to a battery-powered device. An example of the battery-powered device is a lighting device that is powered by a battery.

The improved battery includes a battery module, a controller module, and a cylindrical battery housing.

The battery module is intended for storing energy to provide an electric current. The stored energy is often provided in a chemical form, which is later converted into electrical energy. The electrical energy is provided in a form of an electric current to an electronic device.

The controller module includes a switch, a voltage control unit, a communication unit, and a computing processor.

The switch is adapted to provide an open state and a closed state. In the open state, the switch acts to prevent the electric current to flow from the battery module while in the closed state, the switch serves to allow the electric current to flow from the battery module.

The voltage control unit is adapted to receive the electric current from the battery module. The voltage control unit is also adapted to provide a measurement of the electric current from the battery module and to provide a measurement of a voltage of the battery module. The voltage control unit is further adapted to convert the voltage of the battery module into a predetermined voltage.

The communication unit is adapted to receive commands from an external computing device via a wireless means. The external computing device often refers to a smartphone, which is a handheld personal computer that is installed with a mobile operating system and multiple software applications. The wireless means refers to a communication device using a wireless communication protocol, such as Bluetooth and WiFi.

The computing processor unit is adapted to generate control signals according to the commands from the communication unit. The computing processor unit is also adapted to send the generated control signals to the switch and/or to the voltage control unit.

The computing processor is further adapted to receive the measurement of the electric current and the measurement of the voltage from the voltage control unit. The computing processor then derives at least one parameter according to the measurement of the electric current and the measurement of the corresponding voltage. The derived parameter can refer to the amount of stored energy that is remained in the power module. The computing processor later transmits the at least one derived parameter to the communication unit, which is adapted to transmit out the at least one parameter.

The cylindrical battery housing includes two electrical terminals. The battery housing encloses the battery module and the controller module while one of the electrical terminals is adapted to receive the predetermined voltage from the voltage control unit and to transmit the predetermined voltage to the electronic device.

The communication unit can include a Bluetooth transceiver, which is configured to provide wireless communication using the Bluetooth communication protocol. The battery module can include an electrochemical cell. The electrochemical cell refers to a device that is capable of generating electrical energy from chemical reactions. An example of the electrochemical cell is an alkaline battery of AA-size or AAA side. The controller module can be provided in a form of a printed-circuit-board (PCB).

The application also provides a battery-powered device, which includes one or more improved batteries. The number of batteries used for powering the device depends on the operating voltage of the battery-powered device. For example, some battery-powered devices are designed to operate with a single AA-size battery while other battery-power devices are configured to operate with two AA-size batteries. Both batteries can include only improved batteries of AA-size. They can also include one improved battery of AA-size and one other type of AA-size battery, such as a lithium-ion battery.

In one implementation, the battery-powered device includes a plurality of light emitting diodes.

The application also provides a computer implemented method for selectively controlling at least one improved battery of at least one battery-powered device. The method includes selectively placing a switch of the at least one improved battery in a closed state and/or an open state, thereby selectively switching on and/or switching off the at least one battery-powered device. For an example, one or more light emitting diodes of a battery-powered lighting device can be selectively turned on or turned off by an application of a computing device, which includes the computer implemented method.

The computer implemented method can further include selectively placing the switch of the at least one improved battery in the closed state and/or in the open state at a predetermined time or after a predetermined duration, thereby selectively switching on and/or switching off the at least one battery-powered device at the predetermined time or after the predetermined duration.

The computer implemented method can also include selectively placing the switch of the at least one improved battery in the closed state and in the open state at a predetermined frequency with a predetermined duty cycle, thereby selectively switching on and switching off the at least one battery-powered device at the predetermined frequency with the predetermined duty cycle. This allows one or more light emitting diodes of a battery-powered lighting device to be selectively turned on and turned off, by the application of the computing device, to provide a blinking pattern.

### BRIEF DESCRIPTION OF THE DRAWINGS

The subject matter of the application is described in greater detail in the accompanying Figures, in which

FIG. 1 illustrates a system comprising a battery-powered lighting device with an improved battery and a smartphone for controlling operational states of the improved battery,

FIG. 2 illustrates a circuit block diagram of the system of FIG. 1,

FIG. 3 illustrates a variant of the system of FIG. 1,

FIG. 4 illustrates a further variant of the system of FIG. 1,

FIG. 5 illustrates a battery assembly comprising the improved batteries of the system of FIG. 1,

FIG. 6 illustrates a battery assembly comprising the variants of the improved batteries of the system of FIG. 1, and

FIG. 7 illustrates another battery assembly comprising the variants of the improved batteries of the system of FIG. 1.

### DETAILED DESCRIPTION OF THE PREFERRED EMBODIMENTS

In the following description, details are provided to describe the embodiments of the specification. It shall be apparent to one skilled in the art, however, that the embodiments may be practiced without such details.

Some parts of the embodiments have similar parts. The similar parts may have the same names or similar part numbers with an alphabet symbol or prime symbol. The description of one part applies by reference to another similar part, where appropriate, thereby reducing repetition of text without limiting the disclosure.

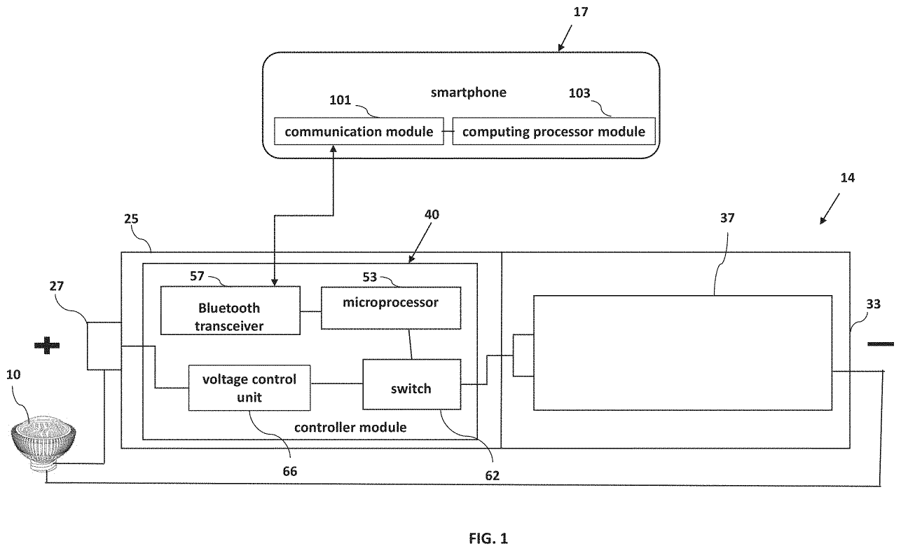

FIG. 1 shows a system that includes a lighting device 10 with an improved battery 14 that is communicatively coupled with a smartphone 17. The improved battery 14 is electrically connected to the lighting device 10. The lighting device 10 can include a plurality of light emitting diodes (LED). The smartphone 17 is a handheld personal computer installed with a mobile operating system and multiple software applications.

The improved battery 14 includes a cylindrical AA-size battery housing 25 with a detachable AAA-size alkaline battery 37 and a controller module 40. The alkaline battery 37 and the controller module 40 are placed inside the battery housing 25.

The battery housing 25 includes a positive electrical terminal 27 and a negative electrical terminal 33. These electrical terminals are placed on both ends of the hollow body. These terminals 27 and 33 are electrically connected to conductive terminals of the lighting device 10.

The alkaline battery 37 has a cathode and an anode. The anode is electrically connected to the negative electrical terminal 33 of the battery housing 25 while the cathode is electrically connected to the controller module 40.

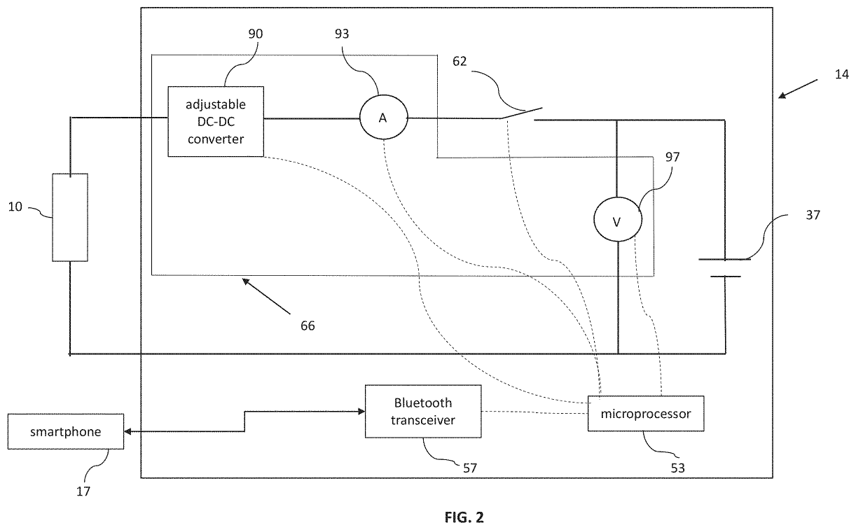

FIG. 2, which shows a circuit diagram of the improved battery 14. The controller module 40 includes a microprocessor 53, a Bluetooth transceiver 57, an electronic switch 62, and a voltage control unit 66, wherein the voltage control unit 66 includes an adjustable DC to DC converter 90, a voltmeter 97, and an ammeter 93.

The cathode of the alkaline battery 37 is electrically connected to a port of the electronic switch 62 while another port of the electronic switch 62 is electrically connected to a terminal of the ammeter 93. Another terminal of the ammeter 93 is electrically connected to an input port of the adjustable DC to DC converter 90. An output port of the DC to DC converter 90 is electrically connected to an electrical terminal of the lighting device 10 while another electrical terminal of the lighting device 10 is electrically connected to the anode of alkaline battery 37. In other words, the alkaline battery 37, the electronic switch 62, the ammeter 93, the adjustable DC to DC converter 90, and the lighting device 10 are connected sequentially in series.

Referring to the voltmeter 97, an electrical terminal is electrically connected to the cathode of the alkaline battery 37 while another electrical terminal is electrically connected to the anode of the alkaline battery 37 such that the voltmeter 97 is connected to the alkaline battery 37 in parallel.

The microprocessor 53 is electrically connected to the electronic switch 62, to the adjustable DC to DC converter 90, to the voltmeter 97, to the ammeter 93, and to the Bluetooth transceiver 57.

The Bluetooth transceiver 57 is configured to provide wireless communication using the Bluetooth communication protocol.

The electronic switch 62 is provided in a form of a solid-state electronic switching device, which is configured to be activated by a control signal.

Referring to the smartphone 17, it includes a communication module 101, and a computing processor module 103. The communication module 101 is electrically connected to the computing processor module 103.

The communication module 101 includes a wireless communication transceiver for providing wireless communication using Bluetooth communication protocol.

The computing processor module 103 includes a computing processor and a memory, which stores instructions of a battery management software application.

In use, the alkaline battery 37 inside the improved battery 14 is intended for converting chemical energy into electrical energy for powering the lighting device 10.

Referring to the controller module 40, the voltmeter 97 is intended for measuring the output voltage of the alkaline battery 37.

The electronic switch 62 acts to provide an open circuit or a closed circuit. In detail, the electronic switch 62 can be activated by a control signal for placing the electronic switch 62 in an open mode or in a closed mode. In the open mode, the electronic switch 62 prevents the electric current from the alkaline battery 37 from flowing through the electric circuit, causing the open circuit to form. In the closed mode, the electronic switch 62 allows the electric current to flow through the electric circuit, causing the closed circuit to form. The open mode is often the default mode.

The ammeter 93 is used for measuring the electric current of the closed circuit.

In the closed circuit, the adjustable DC to DC converter serves to convert the voltage of the alkaline battery 37 to a predetermined output voltage that is suitable for driving the lighting device 10.

The Bluetooth transceiver 57 is intended for transmitting data to and for receiving data from the smartphone 17.

The microprocessor 53 acts to execute instructions according to the battery management software application.

Referring to the smartphone 17, it is intended for controlling the operation of the lighting device 10.

In detail, a user can provide an instruction to the battery management software application of the smartphone 17 to turn on the lighting device 10 with desired light intensity.

The computing processor module 103 of the smartphone 17 then executes the received instructions according to an algorithm of the battery management software application and later sends corresponding commands to the communication module 101 of the smartphone 17. The communication module 101 afterwards transmits the received commands to the transceiver 57 of the improved battery 14.

The transceiver 57 then receives the transmitted commands and later transmits to the microprocessor 53 of the improved battery 14.

The microprocessor 53 afterward receives the transmitted commands and later processes the received commands to generate corresponding control signals for activating the electronic switch 62.

The corresponding control signals then activate the electronic switch 62 for placing the electronic switch 62, which is placed in the default open mode, in the closed mode. The DC voltage of the cathode of the alkaline battery 37 is later transmitted to the input of the DC-DC converter 90.

The corresponding control signals also activate the adjustable DC to DC converter 90 to receive the DC voltage and to convert the received DC voltage into a predetermined DC voltage, according to the control signal, for transmitting to the positive electrical terminal 27 of the improved battery 14 and then to the lighting device 10. The predetermined DC voltage then acts to power the lighting device 10 to emit light that has light intensity according to the value of the predetermined DC voltage.

The user can also enter an instruction to the battery management software application to turn off the lighting device 10. This instruction is later transmitted to the microprocessor 53 of the improved battery 14. The microprocessor 53 then sends a corresponding control signal for placing the electronic switch 62 in the open mode. In the open mode, the electronic switch 62 prevents the electric current from flowing from the electrochemical cell 47 to the lighting device 10, thereby stopping the lighting device 10 from emitting light.

The user can also provide instruction to the battery management software application for turning on/off the lighting device 10 at a predetermined frequency with a pre-determined duty cycle.

This instruction is later transmitted to the microprocessor 53 of the improved battery 14. The microprocessor 53 then activates the electronic switch 62 such that the electronic switch 62 is placed in the open mode and then in the close mode alternately at the predetermined frequency with the predetermined duty cycle. This enables the LEDs of the lighting device 10 to operate in a blinking mode.

The battery management software application can also include an algorithm for turning on/off the lighting device 10 with varying predetermined frequency and with varying predetermined duty cycle. This then allows varying electric current to flow to the LEDs of the light device for providing variations of luminous characteristics of the LEDs.

The user can also use the battery management software application to make a query to retrieve information indicating the health status of the improved battery 14. These battery health indicators can include, but not limited to, remaining capacity of the battery 14 and voltage output from the battery 14.

The query is then transmitted to the microprocessor 53 of the improved battery 14. The microprocessor 53 later activates the ammeter 93 to measure the electric current flowing from the alkaline battery 37 and activates the voltmeter 97 to measure the output voltage of the alkaline battery 37. The microprocessor 53 afterward determines the remaining capacity of the alkaline battery 37 according to measurements of the electric current and of the output voltage.

The microprocessor 53 then transmits the information on the remaining capacity of the alkaline battery 37 and the output voltage measurement, via the transceiver 57, to the smartphone 17 for display to the user.

In one implementation, the smartphone 17 is communicatively connected to a plurality of lighting devices that are powered by the improved batteries 14. In use, the user can use the battery management software application to selectively control the operation of one or more of the improved batteries 14. For an example, the user can turn on or turn off a group of the lighting devices at the same time.

In a general sense, the Bluetooth transceiver 57 can be replaced by a transceiver that uses another communication protocol, such as WiFi, Zigbee, Sigfox, LoRa, and Narrowband IoT (NB-IoT).

The improved battery 14 can have different aspects.

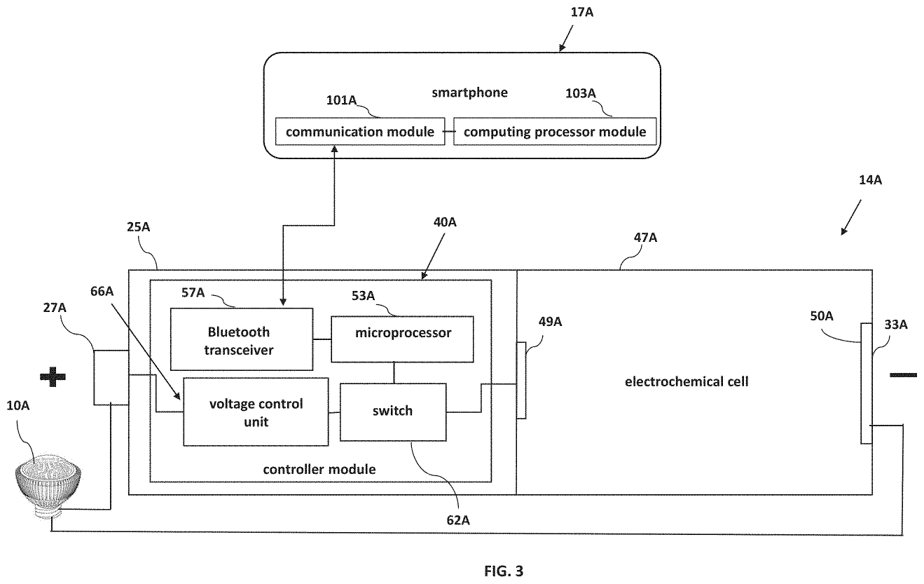

FIG. 3 shows a module that includes a lighting device 10A with an improved battery 14A that is communicatively coupled with a smartphone 17A. The improved battery 14A is electrically connected to the lighting device 10A.

The improved battery 14A is a variant of the improved battery 14. The improved battery 14A includes a cylindrical AA-size battery housing 25A, an electrochemical cell 47, and a built-in controller module 40. The electrochemical cell 47 and the controller module 40A are provided inside the battery housing 25A. A cathode 49A of the electrochemical cell 47 is electrically connected to the controller module 40A while an anode 33A of the electrochemical cell 47 is electrically connected to a negative terminal 33A of the battery housing 25A. The controller module 40A is also electrically connected to a positive terminal 27A of the battery housing 25A.

Arrangement of parts of the controller module 40A of the improved battery 14A and the arrangement of the corresponding parts of the controller module 40 of the improved battery 14, which are described above, are similar. The corresponding parts also have similar functions.

The smartphone 17A is also provided with a battery management software application that is described above.

In one implementation, the controller module 40 is provided in a form of a printed-circuit-board (PCB) that is integrated in the battery housing 25A.

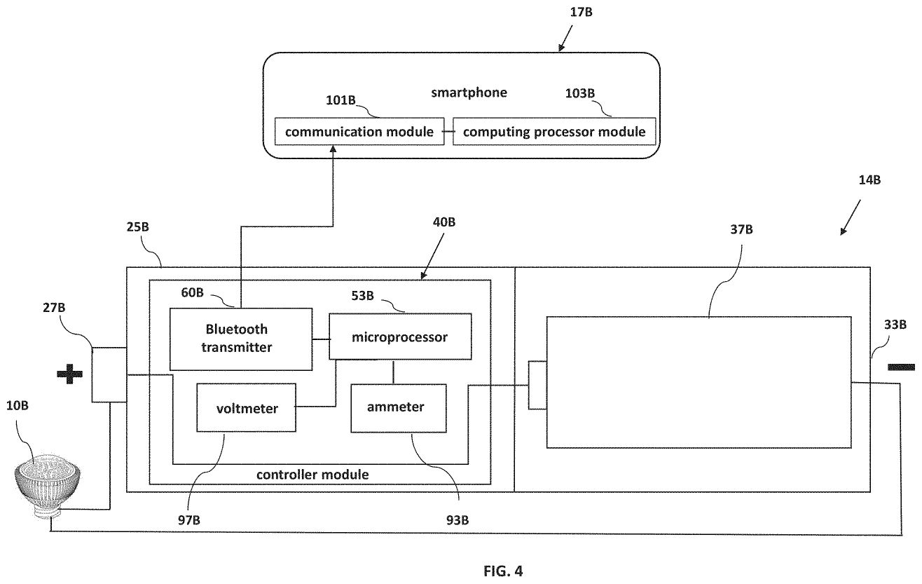

FIG. 4 shows a further module that includes a lighting device 10B with an improved battery 14B that is communicatively coupled with a smartphone 17B. The improved battery 14B is electrically connected to the lighting device 10B.

The improved battery 14B is another variant of the improved battery 14. The improved battery 14B includes a cylindrical AA-size battery housing 25B with an AAA-size rechargeable alkaline battery 37B and a controller module 40B. The alkaline battery 37B and the controller module 40B are placed inside the battery housing 25B.

The controller module 40B includes a microprocessor 53B, a Bluetooth transmitter 60B, a voltmeter 97B, and an ammeter 93B.

A cathode of the alkaline battery 37B is electrically connected to a terminal of the ammeter 93. Another terminal of the ammeter 93B is electrically connected to an electrical terminal of the lighting device 10B while another electrical terminal of the lighting device 10B is electrically connected to an anode of the alkaline battery 37B. In other words, the alkaline battery 37B, the ammeter 93B, and the lighting device 10B are connected sequentially in series.

The voltmeter 97B is electrically connected to the battery 37B in parallel.

The microprocessor 53B is electrically connected to the Bluetooth transmitter 57B, to the voltmeter 97B, and to the ammeter 93B.

In use, the microprocessor 53B is intended for executing instructions to activate the voltmeter 97B for measuring the output voltage of the alkaline battery 37B and to activate the ammeter 93B for measuring the electric current flowing from the alkaline battery 37B. The microprocessor 53B then transmits the measurements of the voltage and the electric current to the Bluetooth transmitter 57B for transmitting the measurements to a smartphone or a computing device.

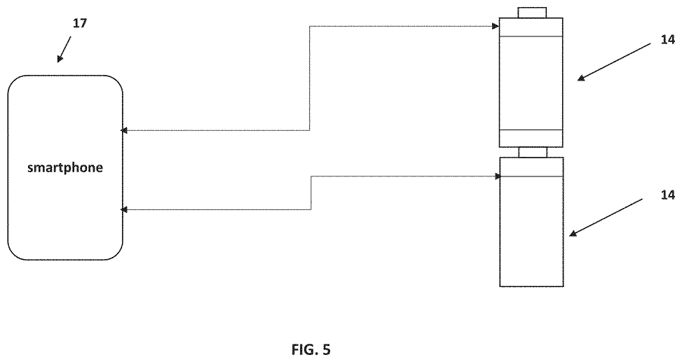

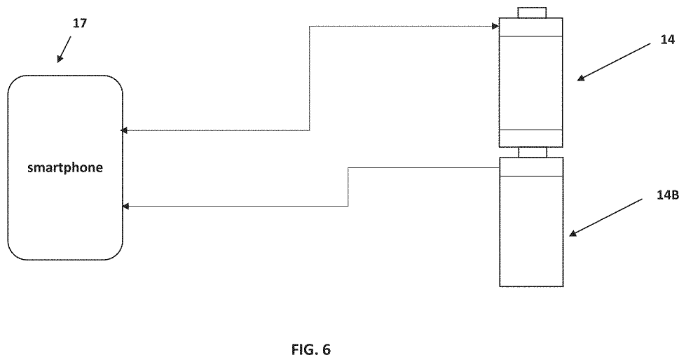

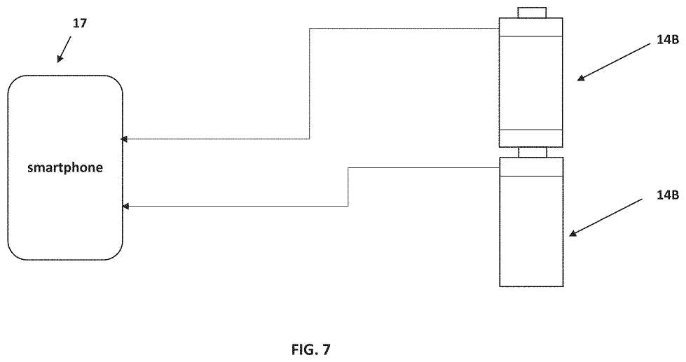

FIGS. 5, 6, and 7 show different battery assemblies comprising the improved batteries 14 and 14B, wherein these improved batteries are individually communicatively connected to a smartphone 17. The battery assembles are intended for providing output voltages that are suitable for different electronic devices that have differing voltage requirements.

In a general sense, the alkaline batteries 37 and 37B can be replaced by other types of electrochemical cells, such as lithium-ion battery and nickel-metal hydride battery (NiMh).

The improved battery 14 provides several benefits.

The improved battery 14 allows the operation of the lighting device to be controlled by a battery management software application of a smartphone. The software application can control a group of lighting devices to generate lighting effects such as dimming and blinking. The software application can also include a timer function for turning on/off the lightings at a predetermined time or after a predetermined duration. Furthermore, the software application also allows a user to check how much power capacity is remained in the improved battery 14.

In short, the user can use the smartphone to switch on/off the lightings individually or as a group remotely and conveniently from one location. This saves his hassle to reach different locations to turn the lightings on/off individually.

The embodiments can also be described with the following lists of features or elements being organized into an item list. The respective combinations of features, which are disclosed in the item list, are regarded as independent subject matter, respectively, that can also be combined with other features of the application.

1. A battery for an electronic device, the battery comprising,
a battery module for storing energy to provide an electric current,
a controller module comprising
   a switch, the switch providing
      an open state for preventing the electric current to flow from the battery module, and
      a closed state for allowing the electric current to flow from the battery module,
   a voltage control unit being adapted for
      receiving the electric current from the battery module,
      providing a measurement of the electric current from the battery module,
      providing a measurement of a voltage of the battery module, and
      converting the voltage of the battery module into a predetermined voltage,
   a communication unit being adapted for receiving commands from an external computing device via a wireless means,
   a computing processor unit being adapted
      for generating control signals according to the commands from the communication unit,
      for sending the generated control signals to the switch and/or the voltage control unit,
   the computing processor further adapted
      for receiving the measurement of the electric current and the measurement of the voltage from the voltage control unit,
      for deriving at least one parameter according to the measurement of the electric current and the measurement of the corresponding voltage, and
      for transmitting the at least one parameter to the communication unit, wherein
      the communication unit is adapted to transmit out the at least one parameter, and
   a battery housing with two electrical terminals,
the battery housing enclosing the battery module and the controller module, and one of the electrical terminals receiving the predetermined voltage from the voltage control unit.

2. The battery according to item 1, wherein the communication unit comprises a Bluetooth transceiver.

3. The battery according to item 1 or 2, wherein the battery module comprises an electrochemical cell.

4. The battery according to one of items 1 to 3, wherein the controller module is provided in a form of a printed-circuit-board.

5. A battery-powered device comprising at least one battery according to one of items 1 to 4.

6. The battery-powered device according to item 5, the battery-powered device further comprising a plurality of light emitting diodes.

7. A computer implemented method for controlling at least one battery according to one of items 1 to 4 of at least one battery-powered device, the method comprising placing a switch of the at least one battery in a closed state and/or an open state, thereby switching on and/or switching off the at least one battery-powered device.

8. The computer implemented method according to item 7, the method further comprising placing the switch of the at least one battery in the closed state and/or in the open state at a predetermined time or after a predetermined duration, thereby switching on and/or switching off the at least one battery-powered device at the predetermined time or after the predetermined duration.

9. The computer implemented method according to item 7 or 8, the method further comprising placing the switch of the at least one battery in the closed state and in the open state at a predetermined frequency with a predetermined duty cycle, thereby switching on and switching off the at least one battery-powered device at the predetermined frequency with the predetermined duty cycle.

Although the above description contains much specificity, these should not be construed as limiting the scope of the embodiments but merely providing illustration of the foreseeable embodiments. Especially the above stated advantages of the embodiments should not be construed as limiting the scope of the embodiments but merely to explain possible achievements if the described embodiments are put into practise. Thus, the scope of the embodiments should be determined by the claims and their equivalents, rather than by the examples given.

### REFERENCE NUMBERS:

10 battery-powered lighting device

14 improved battery

17 smartphone

25 cylindrical battery housing

27 positive electrical terminal

33 negative electrical terminal

37 AAA-size battery

40 controller module

53 microprocessor

57 Bluetooth transceiver

62 electronic switch

66 voltage control unit

90 adjustable DC-DC converter

93 ammeter

97 voltmeter

101 communication module

103 computing processor module

10A battery-powered lighting device

14A improved battery

17A smartphone

25A cylindrical battery housing

27A positive electrical terminal

33A negative electrical terminal

40A controller module

47A electrochemical cell

49A cathode of the electrochemical cell

50A anode of the electrochemical cell

53A microprocessor

57A Bluetooth transceiver

62A electronic switch

66A voltage control unit

90A adjustable DC-DC converter

93A ammeter

97A voltmeter

101A communication module

103A computing processor module

10B battery-powered lighting device

14B improved battery

17B smartphone

25B cylindrical battery housing

27B positive electrical terminal

33B negative electrical terminal

37B AAA-size battery

40B controller module

53B microprocessor

60B Bluetooth transmitter

93B ammeter

97B voltmeter

101B communication module

103B computing processor module

1. A battery for an electronic device, the battery comprising:
a battery module for storing energy to provide an electric current,
a controller module comprising:
a switch, the switch providing:
an open state for preventing the electric current to flow from the battery module, and
a closed state for allowing the electric current to flow from the battery module,
a voltage control unit being adapted for:
receiving the electric current from the battery module,
providing a measurement of the electric current from the battery module,
providing a measurement of a voltage of the battery module, and
converting the voltage of the battery module into a predetermined voltage,
a communication unit being adapted for receiving commands from an external computing device via a wireless means,
a computing processor unit being adapted
for generating control signals according to the commands from the communication unit,
for sending the generated control signals to the switch and/or the voltage control unit,
the computing processor further adapted
for receiving the measurement of the electric current and the measurement of the voltage from the voltage control unit,
for deriving at least one parameter according to the measurement of the electric current and the measurement of the corresponding voltage, and
for transmitting the at least one parameter to the communication unit, wherein
the communication unit is adapted to transmit out the at least one parameter, and
a battery housing with two electrical terminals,
the battery housing enclosing the battery module and the controller module, and one of the electrical terminals receiving the predetermined voltage from the voltage control unit.

2. The battery according to claim 1, wherein the communication unit comprises a Bluetooth transceiver.

3. The battery according to claim 1, wherein the battery module comprises an electrochemical cell.

4. The battery according to claim 1, wherein the controller module is provided in a form of a printed-circuit-board.

5. A battery-powered device comprising at least one battery according to claim 1.

6. The battery-powered device according to claim 5, the battery-powered device further comprising a plurality of light emitting diodes.

7. A computer implemented method for controlling at least one battery according to claim 1 of at least one battery-powered device, the method comprising placing a switch of the at least one battery in a closed state and/or an open state, thereby switching on and/or switching off the at least one battery-powered device.

8. The computer implemented method according to claim 7, the method further comprising placing the switch of the at least one battery in the closed state and/or in the open state at a predetermined time or after a predetermined duration, thereby switching on and/or switching off the at least one battery-powered device at the predetermined time or after the predetermined duration.

9. The computer implemented method according to claim 7, the method further comprising placing the switch of the at least one battery in the closed state and in the open state at a predetermined frequency with a predetermined duty cycle, thereby switching on and switching off the at least one battery-powered device at the predetermined frequency with the predetermined duty cycle.
